(19) United States
(12) Patent Application Publication
(10) Pub. No.: US 2016/0186315 A1
(43) Pub. Date: Jun. 30, 2016

(54) DEPOSITION DEVICE AND METHOD FOR DRIVING THE SAME

(71) Applicant: Samsung Display Co., Ltd., Yongin-city (KR)

(72) Inventors: Sung Hon CHI, Seoul (KR); Jin Seok Son, Cheonan-si (KR)

(21) Appl. No.: 14/694,631

(22) Filed: Apr. 23, 2015

(30) Foreign Application Priority Data
Dec. 26, 2014 (KR) 10-2014-0190919

(51) Int. Cl. C23C 14/58; C23C 14/02; C23C 14/34

(52) U.S. Cl. CPC C23C 14/5826; C23C 14/34; C23C 14/022

(57) ABSTRACT

A deposition device including a chamber configured to provide a space in which a process is performed with respect to a substrate; a substrate support arranged on a bottom side of an inner portion of the chamber and on which the substrate is seated; an upper electrode arranged above the substrate support to be spaced apart from the substrate support; a shower head arranged between the substrate support and the upper electrode and configured to come in contact with the upper electrode, and formed to jet a reaction gas or a cleaning gas in a direction of the substrate support; a reaction gas supply pipe penetrating the chamber and installed on the upper electrode; and a cleaning gas supply pipe penetrating the chamber and arranged on the upper electrode independently of the reaction gas supply pipe.

### CROSS-REFERENCE TO RELATED APPLICATION

This application claims priority from and the benefit of Korean Patent Application No. 10-2014-0190919, filed on Dec. 26, 2014,which is hereby incorporated by reference for all purposes as if fully set forth herein.

### BACKGROUND

1. Field

Exemplary embodiments relate to a deposition device and a method for driving the same.

2. Discussion of the Background

A semiconductor device, a display device, or an electronic device may include a substrate and a plurality of thin films formed on the substrate. A method for forming such thin films may briefly be classified as a physical vapor deposition (PVD) method using physical properties, or a chemical vapor deposition (CVD) method using chemical properties.

The CVD method may include a low pressure CVD (LPCVD) method, an atmospheric pressure CVD (APCVD) method, and a high pressure CVD (HPCVD) method in accordance with pressure formed in a chamber. Further, the CVD method may include a plasma enhanced CVD (PECVD) method that makes it possible to form thin films at low temperature.

On the other hand, in a process of forming thin films using the CVD method, a thin film material may be accumulated on an inner wall of a chamber to form a by-product. Such a by-product may act as a contaminant when the thin films are formed on a substrate. Accordingly, a cleaning process for removing the by-product that is formed on the inner wall of the chamber may be performed.

Generally, the cleaning process is performed by supplying a cleaning gas to the inside of the chamber through a path to which a reaction gas required to form the thin films supplies.

However, various conditions, such as a movement distance and a supply amount of the reaction gas that is provided during forming of the thin films, may be different from other conditions, such as a movement distance and a supply amount of the cleaning gas that is provided during a cleaning process. Thus, in the case where the same supply path is used to supply the reaction gas and the cleaning gas, it may be difficult to satisfy both a deposition efficiency of the thin film material deposited on the substrate and a removal efficiency of the by-product formed in the chamber.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments of the present invention provide a deposition device and a method for driving the same, which can heighten both a deposition efficiency of a thin film material deposited on a substrate and a removal efficiency of a by-product formed on an inner wall of a chamber.

Additional features of the invention will be set forth in the description which follows, and in part will be apparent from the description, or may be learned from practice of the invention.

An exemplary embodiment of the present invention discloses a method for driving a deposition device, including: performing a deposition process for forming thin films on a substrate that is seated on a substrate support installed inside a chamber using a reaction gas which flows into a reaction gas supply pipe that is installed on an upper electrode arranged above the substrate support; and performing a cleaning process for removing a by-product that is formed on an inner wall of the chamber using a cleaning gas which flows into a cleaning gas supply pipe that is installed on the upper electrode to be arranged independently of the reaction gas supply pipe.

An exemplary embodiment of the present invention also discloses a deposition device, including a chamber configured to provide a space in which a process is performed with respect to a substrate; a substrate support which is arranged on a bottom side of an inner portion of the chamber and on which the substrate is seated; an upper electrode arranged above the substrate support to be spaced apart from the substrate support; a shower head arranged between the substrate support and the upper electrode to come in contact with the upper electrode, and formed to jet a reaction gas or a cleaning gas in a direction of the substrate support; a reaction gas supply pipe configured to penetrate the chamber and installed on the upper electrode; and a cleaning gas supply pipe configured to penetrate the chamber and installed on the upper electrode to be arranged independently of the reaction gas supply pipe.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a cross-sectional view of a deposition device according to an exemplary embodiment of the present invention.

FIG. 2 is a plan view of a reaction gas supply pipe and a cleaning gas supply pipe of FIG. 1.

FIG. 3 is a flowchart illustrating a method for driving the deposition device of FIG. 1.

FIG. 4 is a flowchart illustrating a step S10 of FIG. 3 in detail.

FIG. 5 is a flowchart illustrating a step S20 of FIG. 3 in detail.

FIG. 6 is a cross-sectional view of a deposition device according to another exemplary embodiment of the present invention.

FIG. 7 is a cross-sectional view of a deposition device according to still another exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements is throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

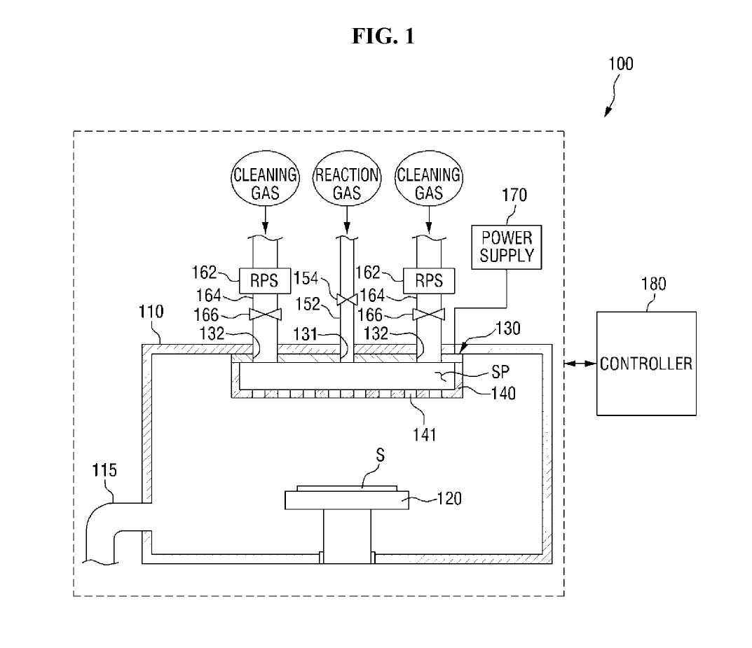

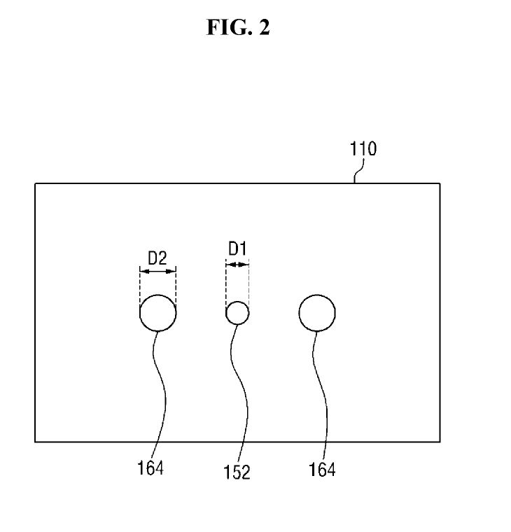

FIG. 1 is a cross-sectional view of a deposition device according to an exemplary embodiment of the present invention, and FIG. 2 is a plan view of a reaction gas supply pipe and a cleaning gas supply pipe of FIG. 1.

Referring to FIG. 1, a deposition device 100 may include a chamber 110, a substrate support 120, an upper electrode 130, a shower head 140, a reaction gas supply pipe 152, a reaction gas valve 154, a remote plasma generator 162, a cleaning gas supply pipe 164, a cleaning gas valve 166, a power supply 170, and a controller 180. The deposition device 100 may be used to form thin films on a substrate S and to remove a by-product formed on an inner wall of a chamber 110.

The chamber 110 is provided the substrate S from an outside, and provides a space in which a deposition process for forming thin films on the substrate S can be performed. On the other hand, the chamber 110 may include a discharge pipe 115 formed on one side wall of the chamber 110 to discharge a cleaning gas that is used in a cleaning process for removing the by-product formed on the inner wall of the chamber 110 after the deposition process and the by-product that is removed by the cleaning gas out of the chamber 110. Although not illustrated, a pump for maintaining an inside of the chamber 110 in a vacuum state during the deposition process may be connected to the discharge pipe 115. Further, although not illustrated, a door for drawing in/out the substrate S may be formed on a side wall of the chamber 110. The chamber 110 may be formed of a stainless steel material, but the present invention is not limited thereto.

The substrate support 120 is installed on a bottom portion of the inside of the chamber 110 to support the substrate S. The substrate support 120 can perform vertical movement and rotation. The substrate support 120 functions as a lower electrode that generates an electric field that is required to convert a reaction gas that flows into the chamber 110 into a plasma state. The upper electrode 130 may be in a ground state.

The upper electrode 130 is arranged above the substrate support 120 and is spaced apart from the substrate support 120, and forms an electric field together with the substrate support 120 to convert the reaction gas that flows into the chamber 110 into a plasma state. The upper electrode 130 may be supplied with high-frequency power from the power supply 160 to be described later.

The upper electrode 130 may be formed in a plate shape, and may include a first through-hole 131 through which the reaction gas supply pipe 152 passes, and a second through-hole 132 through which the cleaning gas supply pipe 164 passes. On the other hand, the upper electrode 130 that is provided in the chamber 110 may be installed to contact with or to be spaced apart from the inner wall of the chamber 110. In the case where the upper electrode 130 contacts the inner wall of the chamber 110, a part of the inner wall of the chamber 110 that contacts the upper electrode 130 may be processed to be insulated from the upper electrode 130.

The shower head 140 is arranged between the substrate support 120 and the upper electrode 130 to contact the upper electrode 130, and is arranged to form a gas inflow space SP into which the reaction gas or the cleaning gas flows together with the upper electrode 130. The shower head 140 includes a plurality of gas jetting holes 141 formed on a portion that faces the substrate support 120, and jets the reaction gas or the cleaning gas that flows into the gas inflow space SP in a direction of the substrate support 120 through the plurality of gas jetting holes 141.

The reaction gas supply pipe 152 is installed in the first through-hole 131 of the upper electrode 130 pass through the wall of chamber 110, and is connected to the gas inflow space SP. The reaction gas supply pipe 152 may have a first diameter D1, and may be arranged in a center portion of the upper electrode 130. The reaction gas supply pipe 152 forms a path for supplying the reaction gas that is required to form the thin films on the substrate S to the gas inflow space SP of the shower head 140. The reaction gas may flow into the gas inflow space SP of the shower head 140 through the reaction gas supply pipe 152 that is installed in the center portion of the upper electrode 130, and then may be provided up to an edge of the substrate S through the gas jetting holes 141 of the shower head 140. The first diameter Dl of the reaction gas supply pipe 152 may differ depending on the amount of reaction gas that is required to form the thin films on the substrate S.

The reaction gas may include a material constituting the thin films that are formed on the substrate S. For example, in the case where the thin film is a silicon oxide layer, the reaction gas may include gases of SiH₄, NH₃, N₂, O₂, and Ar. The reaction gas is not limited thereto, and may differ depending on the kind of the thin film formed on the substrate S.

The reaction gas valve 154 is installed on the reaction gas supply pipe 152 that is outside the chamber 110. The reaction gas valve 154 may be opened or closed to adjust an inflow amount of the reaction gas that flows into the gas inflow space SP of the shower head 140 through the reaction gas supply pipe 152. The reaction gas valve 154 may include a solenoid value or a pneumatic valve.

The remote plasma generator (RPS) 162 is installed outside the chamber 110 to convert the cleaning gas into a plasma state and to supply the plasma cleaning gas to the inside of the chamber 110 when the cleaning process for removing the by-product that is formed on the inner wall of the chamber 110 is performed after the deposition process. The cleaning gas may include, for example, CF₄, C₂F₆, and NF₃, but the present invention is not limited thereto. The cleaning gas may differ depending on the kind of thin film that is formed on the substrate S. In the case where the cleaning gas is NF₃, it is ionized to radicals of NF₂, NF, F, and N by the remote plasma generator 162 to be in a plasma state. The radicals may react on the by-product that is formed on the inner wall of the chamber 110 to convert the by-product into a gas state, and the gaseous by-product may be discharged to the outside by the discharge pipe 115. By this process, the by-product may be removed from the chamber 110.

The cleaning gas supply pipe 164 is connected to the remote plasma generator (RPS) 162, is installed in the second through-hole 132 of the upper electrode 130 to pass through the wall of the chamber 110, and is connected to the gas inflow space SP. The cleaning gas supply pipe 164 forms a path for supplying the cleaning gas in a plasma state (a state where the cleaning gas can react on the by-product), which is required in the cleaning process for removing the by-product formed on the inner wall of the chamber 110, to the gas inflow space SP of the shower head 140.

On the other hand, the cleaning gas supply pipe 164 may be arranged on the upper electrode 130 independently of the reaction gas supply pipe 152, and may be arranged in both side portions of the upper electrode 130. That is, the cleaning gas supply pipe 164 may be arranged on an outside of the reaction gas supply pipe 152. The cleaning gas supply pipe 164 is arranged closer to the inner wall of the chamber 110 in comparison to the reaction gas supply pipe 152, and thus, a movement distance of the cleaning gas in a plasma state can be reduced when the cleaning gas in a plasma state is provided to remove the by-product formed on the inner wall of the chamber 110. If the movement distance of the cleaning gas in a plasma state is lengthened, there is a high possibility that the cleaning gas in a plasma state is lost at some mid-point in the movement. Here, a loss of the cleaning gas in a plasma state may include conversion of the cleaning gas in a plasma state into the cleaning gas in a stabilization state (a state where the cleaning gas does not react on the by-product).

Further, the cleaning gas supply pipe 164 may have a second diameter D2 that is larger than the first diameter D1. The cleaning gas supply pipe 164 may increase a supply amount of the cleaning gas in a plasma state in comparison to a supply amount of the reaction gas in the chamber 110 to compensate for a partial loss of the cleaning gas in a plasma state when supplying the cleaning gas in a plasma state into the chamber 110.

The cleaning gas valve 166 is installed on the cleaning gas supply pipe 164 that is outside the chamber 110. The cleaning gas valve 166 may be opened or closed to adjust an inflow amount of the cleaning gas that flows into the gas inflow space SP of the shower head 140 through the cleaning gas supply pipe 164. The cleaning gas valve 166 may include either a solenoid value or a pneumatic valve.

The power supply 170 is installed outside the chamber 110 and is connected to the upper electrode 130. The power supply 170 is configured to supply a high-frequency power to the upper electrode 130 that forms an electric field to convert the reaction gas that flows into the chamber 110 into a plasma state.

The controller 170 is configured to control all of the processes, including the deposition process for forming the thin films on the substrate S and the cleaning process for removing the by-product that is formed on the inner wall of the chamber 110. The controller 170 may be implemented by a computer, or a similar device using hardware, software, or a combination thereof.

As described above, according to the deposition device 100 of an exemplary embodiment of the present invention, the reaction gas supply pipe 152 and the cleaning gas supply pipe 164 are independently arranged on the upper electrode 130 to convert the reaction gas and the cleaning gas into a plasma state flow into the gas inflow space SP of the shower head 140 through the independent paths. Thus, the conditions, such as the movement distance and the supply amount of the reaction gas that is provided during forming of the thin films on the substrate S, and the conditions, such as the movement distance and the supply amount of the cleaning gas that is provided during the cleaning process, can be differently set.

Accordingly, the deposition device 100 according to an exemplary embodiment of the present invention can increase both the deposition efficiency of the thin film material deposited on the substrate S and the removal efficiency of the by-product formed on the inner wall of the chamber 110.

Next, a method for driving the deposition device 100 of FIG. 1 will be described.

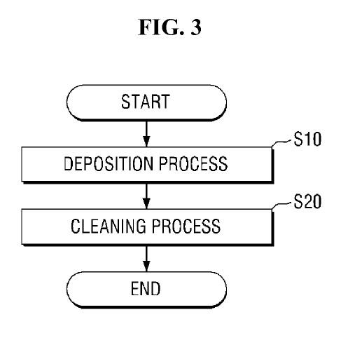

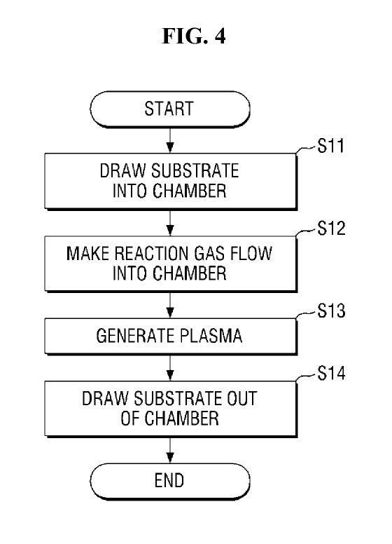

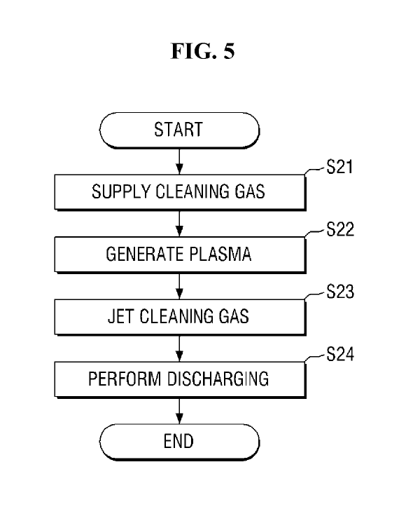

FIG. 3 is a flowchart illustrating a method for driving the deposition device of FIG. 1. FIG. 4 is a flowchart illustrating a step S10 of FIG. 3 in detail, and FIG. 5 is a flowchart illustrating a step S20 of FIG. 3 in detail.

First, referring to FIGS. 1 and 3, in the case of forming thin films on a substrate S, a controller 180 operates to perform a deposition process (S10).

Referring to FIGS. 1, 3, and 4, the deposition process (S10) includes drawing a substrate into a chamber (S11), making a reaction gas flow into the chamber (S12), generating plasma (S13), and drawing the substrate out of the chamber (S14).

The drawing the substrate into the chamber (S11) may include drawing the substrate S into the chamber 110 and seating the substrate on a substrate support 120.

The making the reaction gas flow into the chamber (S12) may include forming a vacuum state within the chamber 110, making the reaction gas flow into a gas inflow space SP of a shower head 140 through a reaction gas supply pipe 152, and jetting the reaction gas onto the substrate S through a gas jetting holes 141 of the shower head 140. The process of making the reaction gas flow into the gas inflow space SP of the shower head 140 through the reaction gas supply pipe 152 may be performed through opening of a reaction gas valve 154.

The generating plasma (S13) generates an electric field between the substrate support 120 and an upper electrode 130 through application of a high-frequency power that is provided from a power supply 160 to the upper electrode 130. Then, the reaction gas is ionized to be in a plasma state, and the reaction gas in a plasma state is deposited on the substrate S to form thin films.

The drawing the substrate out of the chamber (S14) may include drawing the substrate S out of the chamber 110 when the process of forming the thin films on the substrate S is completed.

Then, referring to FIGS. 1 and 3, the controller 180 performs a cleaning process (S20) when the process of forming the thin films on the substrate S is completed.

Referring to FIGS. 1, 3, and 5, the cleaning process (S20) includes supplying a cleaning gas (S21), generating plasma (S22), jetting the cleaning gas (S23), and discharging (S24).

The supplying the cleaning gas (S21) may include making the cleaning gas flow into a remote plasma generator 152.

The generating plasma (S22) may include ionizing the cleaning gas to be in a plasma state using the remote plasma generator 162.

The jetting cleaning gas (S23) may include making the cleaning gas in a plasma state flow into the gas inflow space SP of the shower head 140 through a cleaning gas supply pipe 164, and jetting the cleaning gas in a direction of the substrate support 120 through gas jetting holes 141 of the shower head 140. Through this, a by-product that is formed on the inner wall of the chamber 110 reacts with the cleaning gas in a plasma state (radical state) to convert to a gas state. The process of making the cleaning gas in a plasma state flow into the gas inflow space SP of the shower head 140 through the cleaning gas supply pipe 164 may be performed through opening of a cleaning gas valve 166. In this case, the substrate S may be in a state where the substrate S is drawn out of the chamber 110.

The discharging (S24) may include discharging the by-product in a gas state and a non-reactive cleaning gas through a discharge pipe 115.

Next, a deposition device according to another exemplary embodiment of the present invention will be described.

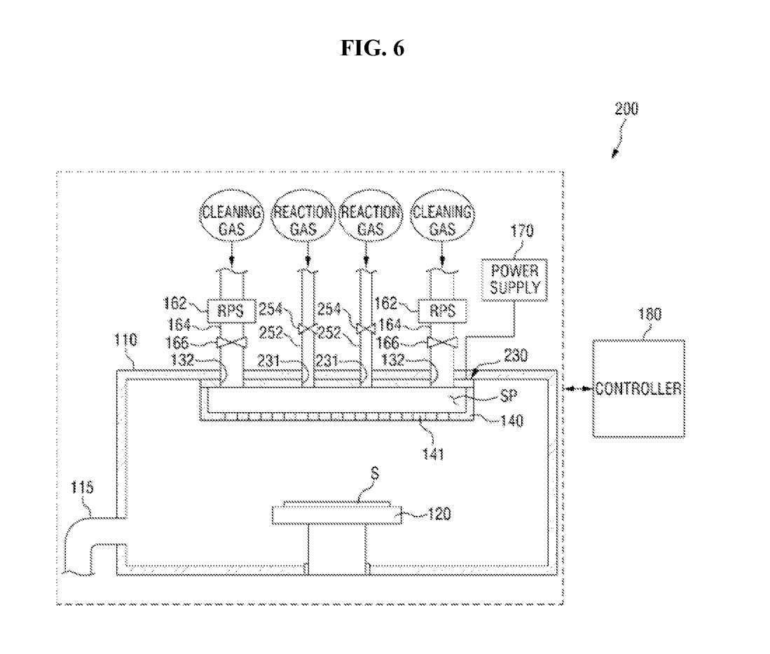

FIG. 6 is a cross-sectional view of a deposition device according to another exemplary embodiment of the present invention.

Referring to FIG. 6, a deposition device 200 according to another exemplary embodiment of the present invention has the same configuration as the configuration of the deposition device 100 of FIG. 1 except for an upper electrode 230, a reaction gas supply pipe 252, and a reaction gas valve 254 that are different from those of the deposition device 100 of FIG. 1. Accordingly, the deposition device 200 according to another exemplary embodiment of the present invention will be described while focusing on the reaction gas supply pipe 252 and the reaction gas valve 254.

The deposition device 200 according to another exemplary embodiment of the present invention may include a chamber 110, a substrate support 120, an upper electrode 230, a shower head 140, a reaction gas supply pipe 252, a reaction gas valve 254, a remote plasma generator 162, a cleaning gas supply pipe 164, a cleaning gas valve 166, a power supply 170, and a controller 180.

Because the chamber 110, the substrate support 120, the shower head 140, the remote plasma generator 162, the cleaning gas supply pipe 164, the cleaning gas valve 166, the power supply 170, and the controller 180 have been described in detail with reference to FIG. 1, duplicate explanations thereof will be omitted.

The upper electrode 230 is similar to the upper electrode 130 of FIG. 1. However, the upper electrode 230 includes first through-holes 231, the number of which corresponds to the number of reaction gas supply pipes 252.

The reaction gas supply pipe 252 is similar to the reaction gas supply pipe 152 of FIG. 1. However, a plurality of reaction gas supply pipes 252 may be arranged in a center portion of the upper electrode 230. The plurality of reaction gas supply pipes 252 may increase the supply amount of a reaction gas which is required to form thin films on a substrate 152 and is supplied to a gas inflow space SP of the shower head 140. Accordingly, in the case where the substrate S is relatively large, a deposition processing time for the substrate S can be reduced.

The reaction gas valve 254 is similar to the reaction gas valve 154 of FIG. 1. However, a plurality of reaction gas valves 254 are installed to correspond to the plurality of reaction gas supply pipes 252.

As described above, according to the deposition device 200 according to another exemplary embodiment of the present invention, the reaction gas supply pipe 252 and the cleaning gas supply pipe 164 are independently arranged on the upper electrode 230 to make the reaction gas and the cleaning gas in a plasma state flow into the gas inflow space SP of the shower head 140 through the independent paths. Thus, various conditions, such as the movement distance and the supply amount of the reaction gas that is provided during forming of the thin films on the substrate S, and the conditions, such as the movement distance and the supply amount of the cleaning gas that is provided during the cleaning process, can be differently set. Further, the supply amount of the reaction gas which is required to form the thin films on the substrate S and is supplied to the gas inflow space SP of the shower head 140 can be increased.

Accordingly, the deposition device 200 according to another exemplary embodiment of the present invention can heighten both the deposition efficiency of the thin film material deposited on the substrate S and the removal efficiency of the by-product formed on the inner wall of the chamber 110, and can reduce the deposition processing time for the substrate S having a large area.

On the other hand, a method for driving the deposition device 200 of FIG. 6 is similar to the method for driving the deposition device 100 of FIG. 1 as described above with reference to FIGS. 3 to 5, and thus, any duplicate explanations thereof will be omitted.

Next, a deposition device according to still another exemplary embodiment of the present invention will be described.

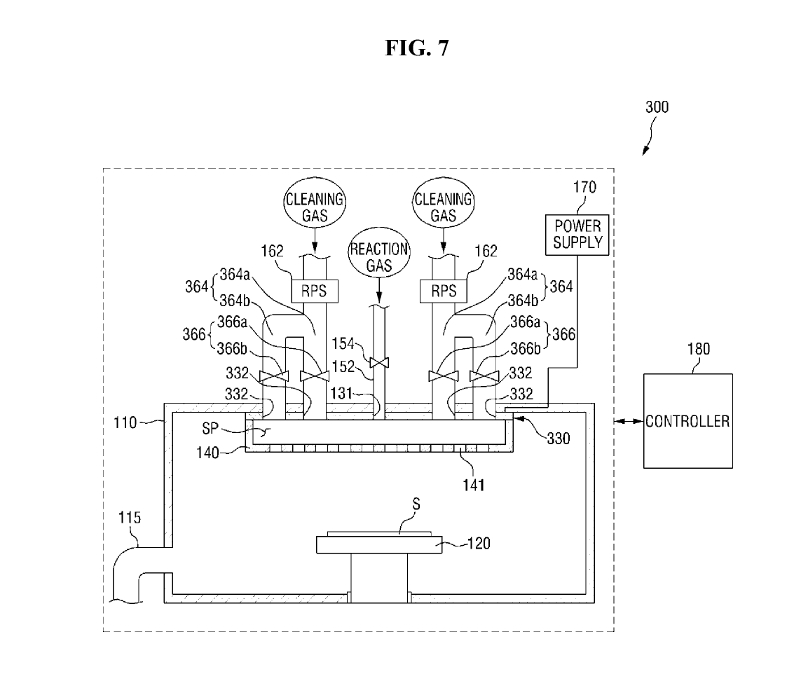

FIG. 7 is a cross-sectional view of a deposition device according to still another exemplary embodiment of the present invention.

Referring to FIG. 7, a deposition device 300 according to still another exemplary embodiment of the present invention has the same configuration as that of the deposition device 100 of FIG. 1, except for an upper electrode 330, a cleaning gas supply pipe 364, and a cleaning gas valve 366 that are different from those of the deposition device 100 of FIG. 1. Accordingly, the deposition device 300 according to still another exemplary embodiment of the present invention will be described with a focus on the upper electrode 330, the cleaning gas supply pipe 364, and the cleaning gas valve 366.

The deposition device 300 according to still another exemplary embodiment of the present invention may include a chamber 110, a substrate support 120, an upper electrode 330, a shower head 140, a reaction gas supply pipe 152, a reaction gas valve 154, a remote plasma generator 162, a cleaning gas supply pipe 364, a cleaning gas valve 366, a power supply 170, and a controller 180.

Because the chamber 110, the substrate support 120, the shower head 140, the reaction gas supply pipe 152, the reaction gas valve 154, the remote plasma generator 162, the power supply 170, and the controller 180 have been described in detail with reference to FIG. 1, any duplicate explanations thereof will be omitted.

The upper electrode 330 is similar to the upper electrode 130 of FIG. 1. However, the upper electrode 330 includes second through-holes 332, the number of which corresponds to the number of cleaning gas supply pipes 364a and 364b that are branched from the remote plasma generator 162.

The cleaning gas supply pipe 364 is similar to the cleaning gas supply pipe 164 of FIG. 1. However, the cleaning gas supply pipe 364 may include the first cleaning gas supply pipe 364a and the second cleaning gas supply pipe 364b that are branched from the remote plasma generator 162. The cleaning gas supply pipe 364 may increase the supply amount of a cleaning gas in a plasma state, which is required in a cleaning process for removing a by-product in the chamber 110 through the first cleaning gas supply pipe 364a and the second cleaning gas supply pipe 364b and is supplied to a gas inflow space SP of the shower head 140. Accordingly, the cleaning processing time for the substrate S can be reduced, and a partial loss of the cleaning gas when the cleaning gas in a plasma state is supplied into the chamber 110 can be compensated for.

The cleaning gas valve 366 is similar to the cleaning gas valve 166 of FIG. 1. However, a plurality of cleaning gas valves 366 are installed to correspond to the first cleaning gas supply pipe 364a and the second cleaning gas supply pipe 364b. For example, the cleaning gas valve 366 may include a first cleaning gas valve 366a and a second cleaning gas valve 366b.

As described above, according to the deposition device 300 according to still another exemplary embodiment of the present invention, the reaction gas supply pipe 152 and the cleaning gas supply pipe 364 are independently arranged on the upper electrode 330 to make the reaction gas and the cleaning gas in a plasma state flow into the gas inflow space SP of the shower head 140 through independent paths. Thus, various conditions, such as the movement distance and the supply amount of the reaction gas that is provided during forming of the thin films on the substrate S, and the conditions, such as the movement distance and the supply amount of the cleaning gas that is provided during the cleaning process, can be differently set. Further, the supply amount of the cleaning gas in a plasma gas, which is required in the cleaning process for removing the by-product formed on the inner wall of the chamber 110, to the gas inflow space SP of the shower head 140 can be increased.

Accordingly, the deposition device 300 according to still another exemplary embodiment of the present invention can enhance both the deposition efficiency of the thin film material deposited on the substrate S and the removal efficiency of the by-product formed on the inner wall of the chamber 110, and can reduce the cleaning processing time for the substrate S. Further, the deposition device 300 can compensate for the partial loss of the cleaning gas in a plasma state when the cleaning gas is supplied into the chamber 110.

On the other hand, a method for driving the deposition device 300 of FIG. 7 is similar to the method for driving the deposition device 100 of FIG. 1 as described above with reference to FIGS. 3 to 5, and thus, any duplicate explanations thereof will be omitted.

According to the deposition device and the method for driving the same according to exemplary embodiments of the present invention, the reaction gas supply pipe and the cleaning gas supply pipe are independently arranged on the upper electrode to make the reaction gas and the cleaning gas in a plasma state flow into the gas inflow space of the shower head through independent paths. Thus, various conditions, such as the movement distance and the supply amount of the reaction gas that is provided during forming of the thin films on the substrate, and other conditions, such as the movement distance and the supply amount of the cleaning gas that is provided during the cleaning process, can be differently set.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A method for driving a deposition device, comprising:
performing a deposition process for forming thin films on a substrate that is seated on a substrate support installed inside a chamber using a reaction gas which flows into a reaction gas supply pipe that is installed on an upper electrode arranged above the substrate support; and
performing a cleaning process for removing a by-product that is formed on an inner wall of the chamber using a cleaning gas which flows into a cleaning gas supply pipe that is installed on the upper electrode to be arranged independently of the reaction gas supply pipe.

2. The method of claim 1, wherein:
the reaction gas supply pipe is arranged in a center portion of the upper electrode; and
the cleaning gas supply pipe is arranged in both side portions of the upper electrode.

3. The method of claim 1, wherein a diameter of the reaction gas supply pipe is smaller than a diameter of the cleaning gas supply pipe.

4. The method of claim 2, further comprising a plurality of reaction gas supply pipes.

5. The method of claim 2, wherein the cleaning process comprises converting the cleaning gas into a plasma state using a remote plasma generator that is installed outside the chamber and supplying the cleaning gas in a plasma state to the cleaning gas supply pipe.

6. The method of claim 5, wherein the cleaning gas supply pipe comprises a first cleaning gas supply pipe and a second cleaning gas supply pipe that are branched from the remote plasma generator.

7. The method of claim 1, wherein:
the deposition process comprises jetting the reaction gas that flows into a gas inflow space through the reaction gas supply pipe in a direction of the substrate using a shower head disposed between the substrate support and the upper electrode; and
the shower head contacts the upper electrode and forms the gas inflow space together with the upper electrode.

8. The method of claim 1, wherein the deposition process comprises forming an electric field between the substrate support and the upper electrode by applying of a high-frequency power from a power supply installed outside the chamber to the upper electrode.

9. The method of claim 1, wherein the cleaning process comprises:
jetting the cleaning gas that flows into a gas inflow space through the cleaning gas supply pipe in a direction of the substrate support using a shower head disposed between the substrate support and the upper electrode; and
the shower head contacts the upper electrode and forms the gas inflow space together with the upper electrode.
